(19) United States
(12) Patent Application Publication
(10) Pub. No.: US 2006/0264006 A1
(43) Pub. Date: Nov. 23, 2006

(54) Method and apparatus for RFID device assembly

(75) Inventors: Kouroche Kian, Altadena, CA (US); Xiao Ming He, Arcadia, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: AVERY DENNISON CORPORATION, PASADENA, CA (US)

(21) Appl. No.: 11/437,033

(22) Filed: May 19, 2006

Related U.S. Application Data
(60) Provisional application No. 60/683,114, filed on May 19, 2005.
(60) Provisional application No. 60/685,218, filed on May 27, 2005.

(51) Int. Cl. H01L 21/00; H01L 21/30

(52) U.S. Cl. 438/464; 438/118; 438/458

(57) ABSTRACT

A process is disclosed for creating semiconductor devices such as RFID assemblies wherein an array of dies is spaced apart at a pitch matching the pitch of straps on a web of straps before they are mounted to a chip carrier substrate. The substrate is then cut into strips to form one or more linear aggregations of dies. The linear aggregation of dies is then transferred by an assembly mechanism onto the web of straps and electrically attached to a plurality of straps or interposers arranged in a corresponding array. The spacing, or pitch, between the dies in the die array may be changed to match the pitch of the straps or interposers in the corresponding array before or after a wafer substrate is removed from the die array. An RFID device created using the process inventive is also disclosed.

### CLAIM OF THE PRIORITY UNDER 35 U.S.C. §119

The present Application for Patent claims priority to Provisional Application No. 60/683,114 entitled “METHOD AND APPARATUS FOR RFID DEVICE ASSEMBLY” filed May 19, 2005, and Provisional Application No. 60/685,218 entitled “METHOD AND APPARATUS FOR RFID DEVICE ASSEMBLY BY SELECTIVE TRANSFER” filed May 27, 2005, both of which are assigned to the assignee hereof and hereby expressly incorporated by reference herein.

### FIELD OF THE INVENTION

The present invention relates generally to manufacturing of semiconductor devices, and more particularly, to a method and apparatus for creating RFID devices.

### BACKGROUND OF THE INVENTION

Automatic identification of products has become commonplace. For example, the ubiquitous barcode label, placed on food, clothing, and other objects, is currently the most widespread automatic identification technology that is used to provide merchants, retailers and shippers with information associated with each object or item of merchandise.

Another technology used for automatic identification products is Radio Frequency Identification (RFID). RFID uses labels or “tags” that include electronic components that respond to radio frequency commands and signals to provide identification of each tag wirelessly. Generally, RFID tags and labels comprise an integrated circuit (IC, or chip) attached to an antenna that responds to a reader using radio waves to store and access the ID information in the chip. Specifically, RFID tags and labels have a combination of antennas and analog and/or digital electronics, which often includes communications electronics, data memory, and control logic.

One of the obstacles to more widespread adoption of RFID technology is that the cost of RFID tags are still relatively high as lower cost manufacturing of RFID tags has not been achievable using current production methods. Additionally, as the demand for RFID tags has increased, the pressure has increased for manufacturers to reduce the cost of the tags, as well as to reduce the size of the electronics as much as possible so as to: (1) increase the yield of the number of chips (dies) that may be produced from a semiconductor wafer, (2) reduce the potential for damage, as the final device size is smaller, and (3) increase the amount of flexibility in deployment, as the reduced amount of space needed to provide the same functionality may be used to provide more capability.

However, as the chips become smaller, their interconnection with other device components, e.g., antennas, becomes more difficult. Thus, to interconnect the relatively small contact pads on the chips to the antennas in RFID inlets, intermediate structures variously referred to as “straps,” “interposers,” and “carriers” are sometimes used to facilitate inlay manufacture. Interposers include conductive leads or pads that are electrically coupled to the contact pads of the chips for coupling to the antennas. These leads provide a larger effective electrical contact area between the chips and the antenna than do the contact pads of the chip alone. Otherwise, an antenna and a chip would have to be more precisely aligned with each other for direct placement of the chip on the antenna without the use of such strap. The larger contact area provided by the strap reduces the accuracy required for placement of the chips during manufacture while still providing effective electrical connection between the chip and the antenna. However, the accurate placement and mounting of the dies on straps and interposers still provide serious obstacles for high-speed manufacturing of RFID tags and labels.

Several possible high-speed strap assembly strategies have been proposed. The first approach, which uses “pick-and-place” machines typically used in the manufacturing of circuit boards for picking up electronic components and placing them on circuit boards, is accurate, but requires expensive machines that ultimately do not deliver a sufficient throughput to justify the increased cost. Another approach, referred to as a “self-assembly process,” is a method in which multiple chips are first dispersed in a liquid slurry, shaken and assembled into a substrate containing chip receiving recesses. Some current processes are described in U.S. Pat. No. 6,848,162, entitled “Method and Apparatus for High Volume Assembly of Radio Frequency Identification Tags,” issued to Arneson, et al. on Feb. 1, 2005; U.S. Pat. No. 6,566,744, entitled “Integrated Circuit Packages Assembled Utilizing Fluidic Self-Assembly,” issued to Gengel on May 20, 2003; and, U.S. Pat. No. 6,527,964, entitled “Methods and Apparatuses for Improved Flow in Performing Fluidic Self Assembly,” issued to Smith et al. on Mar. 4, 2003.

Accordingly, there is a long-felt, but as yet unsatisfied need in the RFID device manufacturing field to be able to produce RFID devices in high volume, and to assemble them at much higher speed per unit cost than is possible using current manufacturing processes.

### SUMMARY OF THE PREFERRED EMBODIMENTS

In accordance with the various exemplary embodiments thereof described herein, a process for creating semiconductor devices, such as RFID assemblies, begins with the provision of an array of semiconductor dies mounted to a substrate and spaced apart at a first pitch, or spacing. For example, a diced semiconductor wafer attached to a wafer sawing, or UV (“blue”) tape is provided in one embodiment. The substrate is stretched in so that the pitch of the dies in one direction matches a pitch between the straps in a plurality of straps. The relative positions of the dies are then fixed to a solidifiable material. The solidified material is cut into strips along a direction parallel to the direction along which the dies are stretched. Each strip, or linear aggregation of dies, is then placed using an assembly machine on a corresponding plurality of straps disposed on a strap web, and the dies contained thereon are electrically coupled to respective ones of the straps. In one embodiment, the process may utilize a pick and place machine to place a linear aggregation of dies instead of one die at the time. The pitch between the dies in the array may be increased to match the pitch of the plurality of straps in the corresponding array. In addition, the array of dies may be expanded in more than one direction when it is expanded to match the pitch of the straps on the strap web.

The solidified material may be created in one embodiment of the process by coating the diced expanded wafer with a solidifiable material. Alternatively, instead of a solidifiable material, the array of dies may be transferred to a rigid substrate and affixed thereto with a UV-sensitive adhesive. Both approaches would allow the cutting of the wafer along one direction to create the strips. In addition, cuts may be made along a second direction perpendicular to the first if the length of the strips will be too long to achieve the creation of a linear aggregation of dies with uniform pitches matching the pitch of the target straps.

The process described herein permits the placement of dies with their contact or, active, side up at constant intervals on a reel-to-reel substrate. Thus, in another approach, the linear aggregation of dies may be sunk into the reel-to-real substrate using such methods as NIR thermocompression. The contacts on the straps may subsequently be printed onto the substrate in a way so as to enlarge the die connectors.

Other features and advantages of the present invention will become apparent to those skilled in the art from the following detailed description. It is to be understood, however, that the detailed description of the various embodiments and specific examples, while indicating preferred and other embodiments of the present invention, are given by way of illustration and not limitation. Many changes and modifications within the scope of the present invention may be made without departing from the spirit thereof, and the invention includes all such modifications.

### BRIEF DESCRIPTION OF THE DRAWINGS

The invention may be more readily understood by referring to the accompanying drawings in which:

FIG. 1 is a high-level flow diagram of a method for manufacturing a semiconductor device such as an RFID device in accordance to a preferred embodiment of the present invention;

FIG. 2 is a detailed flow diagram of the method for manufacturing the semiconductor device of FIG. 1 in accordance to a preferred embodiment of the present invention;

FIG. 3 is a diagram illustrating an expansion of a wafer having a plurality of dies mounted on a substrate pursuant to one preferred embodiment of the present invention;

FIG. 4 is a side view of the plurality of dies of FIG. 3 as displaced on a support platform and fixed in position by being frozen in a layer of ice after the expansion process;

FIG. 5 is a side view of the plurality of dies of FIG. 4 wherein the substrate is being removed in accordance with one preferred embodiments of the present invention;

FIG. 6 is a plan view illustrating a linear aggregation of the plurality of dies from a wafer in accordance to one preferred embodiment of the present invention;

FIG. 7 is a plan view illustrating a placement of the linear aggregation of the plurality of dies onto a corresponding set of straps in a direct contact approach in accordance to one preferred embodiment of the present invention;

FIG. 8 is a side view of a bonding process wherein the linear aggregation of the plurality of dies of FIG. 10 is bonded to the set of straps in accordance with one preferred embodiment of the present invention;

FIG. 9 is a plan view illustrating the placement of the linear aggregation of dies between a plurality of strap wings in an indirect contact approach in accordance with one preferred embodiment of the present invention;

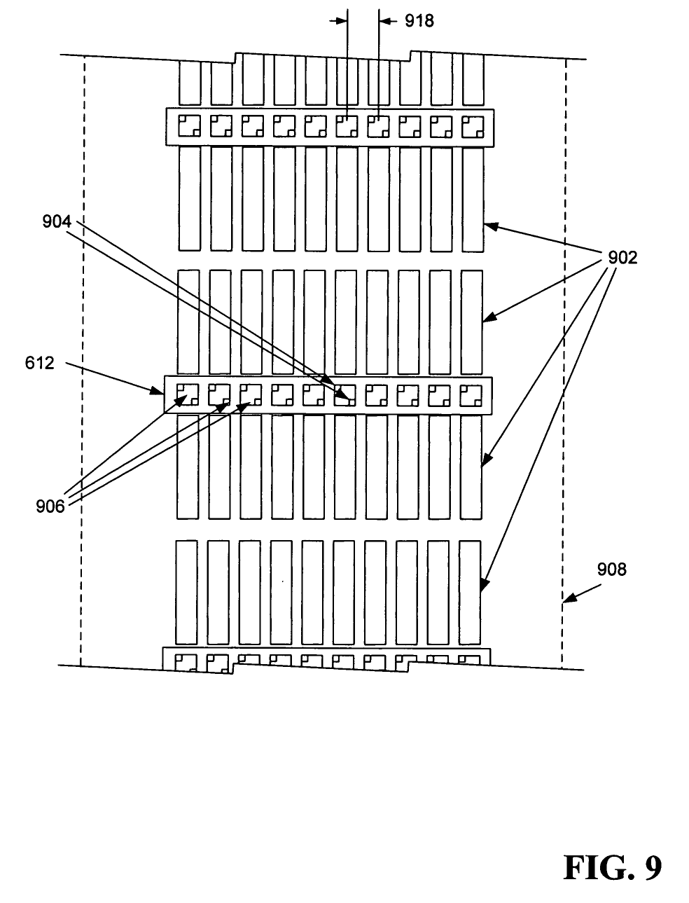

FIG. 10 is a plan view illustrating the coupling of the linear aggregation of dies to the plurality of strap wings in accordance with one preferred embodiment of the present invention;

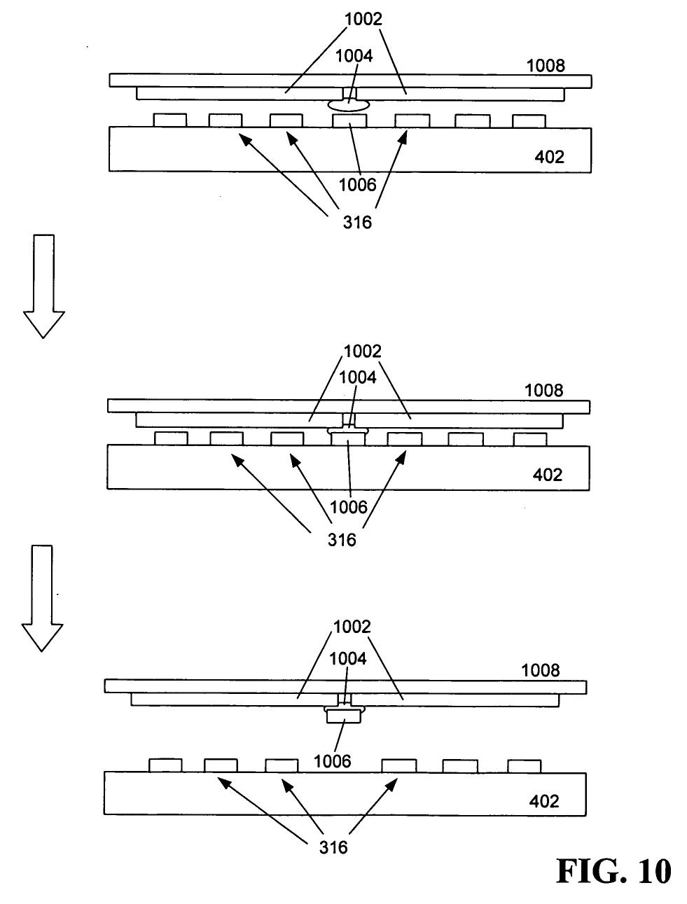

FIG. 11 illustrates a NIR thermocompression process as well as a wire die-to-strap connection process in accordance with one preferred embodiment of the present invention;

FIG. 12 illustrates an process for creating an RFID strap assembly as well as a wire die-to-strap connection process in accordance with one preferred embodiment of the present invention;

FIG. 13 illustrates a tape transfer process in accordance with one preferred embodiment of the present invention;

FIG. 14 illustrates an aggregated die creation process in accordance with one preferred embodiment of the present invention; and,

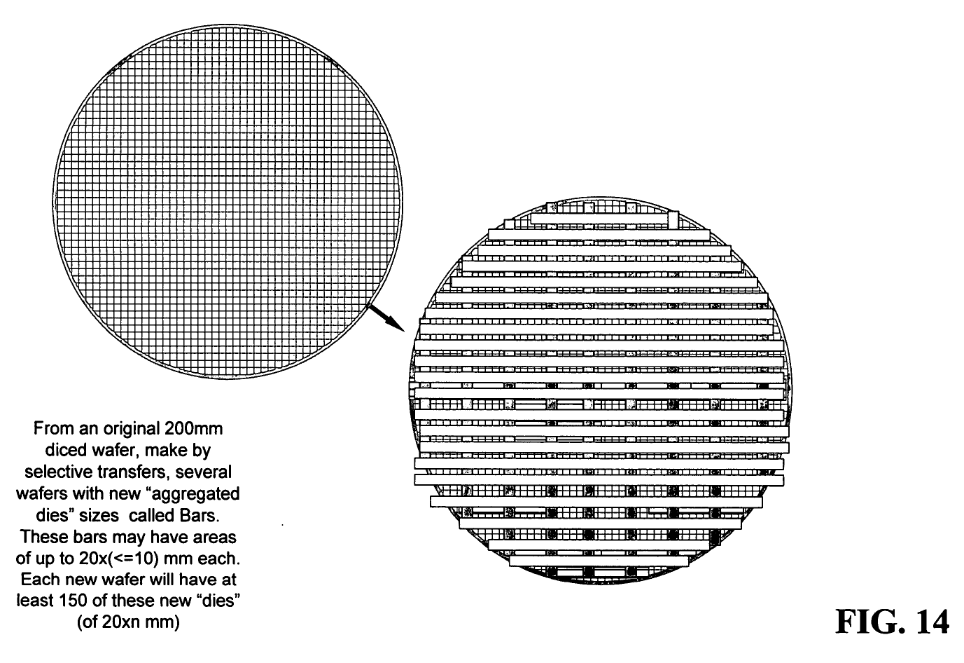

FIG. 15 illustrates a placement of aggregated dies on straps process in accordance with one preferred embodiment of the present invention.

Like numerals refer to like parts throughout the several views of the drawings.

### DETAILED DESCRIPTION OF THE PREFERRED EMBODIMENTS

The present invention provides a multi-die assembly approach to the creation of RFID devices by creating a linear chip carrier to effect the electrical attachment of multiple dies, or chips, to respective straps on a web of straps. Typically, the straps are disposed on the strap web as compact of a form as possible for the specific strap, where a minimum of spacing provided between each strap. The present invention changes the spacing between the dies from an initial pitch, such as a spacing of the dies as they are initially presented on the wafer, to a new pitch on the linear chip carrier to support direct attachment of the dies to straps via a high-speed production process.

In addition, in one embodiment the RFID creation process may utilize printing wire bonding techniques to electrically connect chips to the wings. The combination of the provision of unattached dies and the accurate alignment thereof at a desired spacing enables manufacturers to produce RFID devices at a substantially higher rate than what is currently achieved, and may enable them to reach or exceed rates of one hundred thousand units per hour. This is a level of magnitude higher than the volume achievable by current manufacturing methods, viz., about ten thousand units per hour.

1 Overview

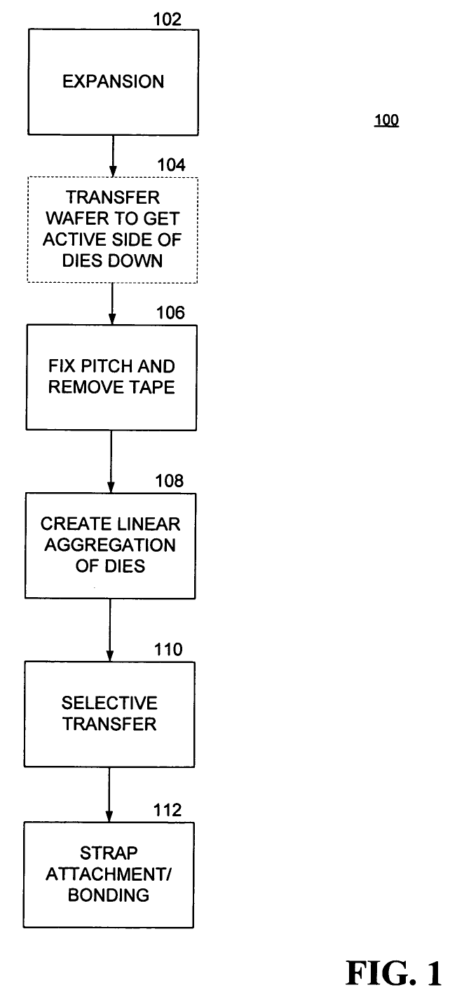

FIG. 1 is a high-level overview of one preferred embodiment of a process 100 for the creation of a chip assembly of the present invention adapted for the manufacturing of RFID devices. In general, the process as illustrated involves four different stages, including an optional expansion step 102, during which the spacing and pitch between each die in an arrangement of dies on a stretchable substrate may be increased to match a predetermined pitch for a web of straps; a pitch fix strap, during which the pitch in the arrangement of dies are fixed; a linear aggregation of dies step 108, where the array of dies are separated into strips, each strip having a predetermined number of dies; and, a selective transfer step 110, in which the array of dies or a subset thereof, respectively positioned in locations that match the pitch of a set of straps on a web, are transferred from the arrangement of dies. In one embodiment, an optional wafer transfer step 104 may be used to selectively position a side of the dies on which the contact pads are located, referred to as the “active side” of the dies, such that the active side is either up or down (the direction of “up” or “down” being defined as a direction with respect to the surface of a floor). Whether the active side needs to be facing up or down will be based on how the dies are to be attached the to the straps, as further described below.

In one embodiment, the active side of the dies are facing down so that the contact pads of each die may be directly attached to a respective contact on a pair wings of each strap. In another embodiment, a method for attaching the dies to the straps using a wire bonding method or high speed printing. As is further detailed below, other portions of the die separation and strap attachment process may be optional and the process described herein may include portions that are not needed for a particular application. Therefore, the following description should be read as illustrating exemplary embodiments of a novel die separation and strap attachment process as practiced in one preferred embodiment of the present invention and should not be taken in a limiting sense.

2. Detailed Overview

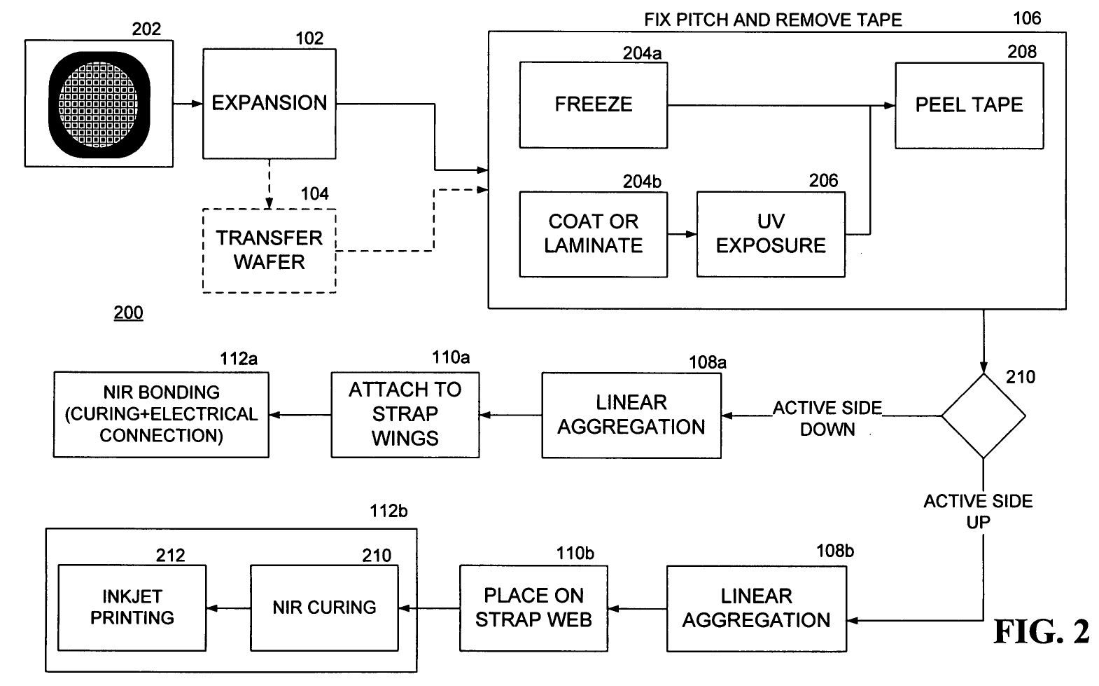

FIG. 2 illustrates, in greater detail, specific steps in the method for creating a semiconductor device (such as an RFID device) as shown in FIG. 1, in accordance with one exemplary embodiment of the present invention. The description of the specific steps in FIG. 2 will refer to other figures as appropriate. The process for creating RFID chip assemblies overcomes two major challenges—whether the process involves the assembly of a chip directly onto an antenna or, alternatively, the assembly of a chip onto a strap before the strap is attached to an antenna. The first hurdle is to attach the chip accurately to specific locations on a structure such as a strap or an antenna. Secondly, the chip has to be attached, both mechanically and electrically, with the structure.

In the present invention, the chip attach solution provides a parallel processing approach in which a plurality of chips are each attached to a corresponding structure simultaneously. However, an issue that arises in the implementation of the above solution is how the dies, which typically are delivered in the form of a diced wafer, will be separated and placed at the appropriate locations. Specifically, after a wafer is fabricated (i.e., after the desired circuitry has been formed on the wafer), it is “diced,” i.e., cut into small rectangular pieces with each piece (i.e., a die or chip) having the complete set of circuitry needed to provide the functions for which it was designed.

Typically, the wafer is held on a carrier such as an adhesive tape, and the wafer, now composed of the cut-up, or “singulated” dies, remain on the carrier after the dicing. The dies are arranged very close to each other on the adhesive tape, forming a dense array, or matrix, with very a small distance, or pitch, between them. However, the distance (pitch) between adjacent antennas (or adjacent straps on the strap web) is typically much larger, usually by an order of magnitude, than the pitch between the dies. Thus, one problem that needs to be solved for the above-described die attach process is the provision of a method to match the pitch of the dies to the pitch of the straps (or antennas).

3 Expand Pitch

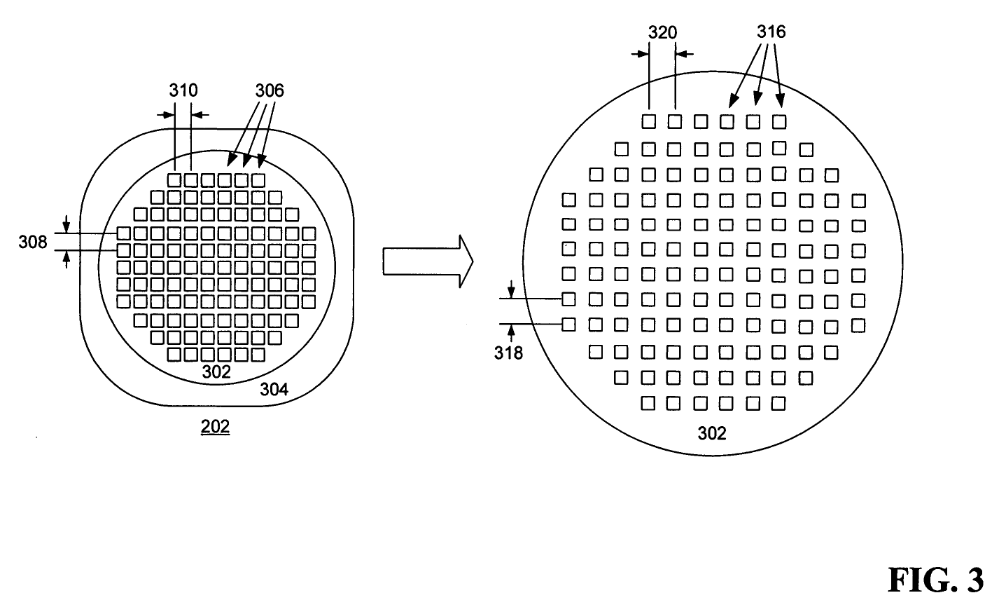

Referring to FIGS. 2 and 3, a wafer assembly 202 includes a plurality of dies 306 arranged in a rectangular array and located on a substrate 302, such as a wafer tape, which is mounted on a “banjo,” or support frame 304. The plurality of dies 306 are initially spaced apart at relatively small pitches 308, 310 in orthogonal directions (i.e., “X” and “Y”-axes), which are not large enough to allow processing of a single chip without disturbing the adjacent chips. Although conventional IC processing methods include stretching the wafer tape by a small amount (viz., on the order of 10%) to allow the removal of individual chips without affecting others, these traditional solutions do not contemplate the stretching of the substrate 302 to increase the pitch between the plurality of dies 306 by many orders of magnitude so that the pitch of the dies will match the pitch of the structures to which they will ultimately be attached. Specifically, it is preferable to expand wafer to get the lines of dies separated in at least one of X or Y directions uniformly to reach a given pitch that matches the pitch that exists between each strap on the web of straps, where the X and Y axes are defined with regards to the planar surface of the wafer. In one embodiment, the wafer is expanded in one dimension such that the dies are precisely separated in only one axis (i.e., one direction). In another embodiment, the expansion may be multi-directional—e.g., where the wafer is expanded along both the X and Y axes.

In one preferred embodiment of the present invention, the substrate 302 is stretched one or more times so that one of the pitches 308, 310 are increased to larger pitches 318, 320, and to arrive at a larger-sized second array of dies 316. In another embodiment, the substrate 302 may be stretched one or more times in one or more directions. In one preferred embodiment, the material used for the substrate 302 is linearly and uniformly stretchable in two orthogonal axes. For example, a polymer substrate film with adhesive bonding may be used. The film is attached to the back of the wafer (i.e., the side of the wafer opposite the “active” side of the wafer, the active side being side of the wafer having the contact pads of the dies). The film is then stretched. Then, the film is subjected to UV light, which will detach the adhesive before the wafer is attached to another film or substrate. During the transfer, the stretched substrate, such as substrate 302, may be scored or cut to enable the second substrate to be more easily stretched. The process of stretching, de-tacking and transferring may be continued indefinitely until a desired pitch (or orthogonal pitches) between the dies is (are) reached. In another preferred embodiment, the stretching does not have to be uniform and may be of a greater magnitude in one axis than another. Thus, the pitch in one direction may be stretched to match the pitch between the straps, while the pitch in the other direction may be stretched to an extent just large enough to allow easier handling of the dies.

It should be obvious to those of ordinary skill in the art that although the description contained herein with regard to the change in pitches between the dies in the plurality of dies 306 has been directed to an operation to increase the pitches in one or more dimensions, the techniques may also be equally be applicable to operations to decrease the pitches between the dies in one or more dimensions. Further, where other methods are used to both align dies and simultaneously change the pitch between the dies, the stretching operation as described in the expansion stage 102 may be eliminated.

After the plurality of dies 306 has been stretched to arrive at the larger-sized second array of dies 316, the next step is to prepare plurality of dies for the linear aggregation stage 108 by fixing the pitch between the dies and removing the substrate 302 using a series of steps as represented by block 106 of FIG. 2.

3.1 Adjusting Alignment

Although the tape removal process as described above is not intended to affect the position of the dies in the array of dies 316, the alignment of the dies after step 210 may still not be as accurate as desired. Thus, a precision die alignment grid may be used to further align the array of dies. Further, a fixation grid may be also be used to fix the position and orientation of the dies in the array of dies 316 for transportation or other processing purposes, where the fixation grid includes a plurality of apertures sized to retain the dies securely.

The precision die alignment grid and the die fixation grid can be fabricated of, in one embodiment, semiconductor materials (e.g., silicon), using well-known micromachining techniques, in a manner similar to those described in U.S. Pat. No. 6,573,112, issued to Kono et al.

4 Fix Pitch & Remove Tape

As noted in the series of steps shown in FIG. 2 as well as further described below, the process includes the stretching or expansion step 102 and two alternatives to fix the pitch and remove the tape, or the substrate 302 of FIG. 2, in pitch fix and tape removal step 106. In one embodiment, a solidifiable substance such as a liquid is first introduced to the plurality of dies 306 and frozen before a tape peel step 208, where the first substrate 302 is removed from the dies, occurs. In another embodiment, a coating or laminate step 204b, where a tape attached to the dies are either coated or laminated using a UV-curable material is first performed, before a UV exposure step 206 exposes and thereby simultaneously solidifies the UV-curable material and de-tacks the adhesive that is used on the substrate 302 to adhere the dies to it.

4.1 Freeze/Peel

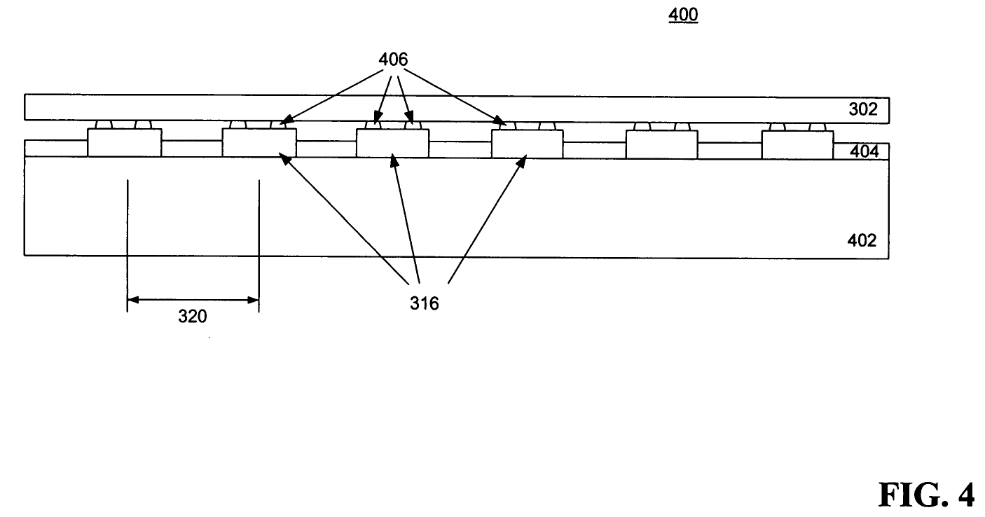

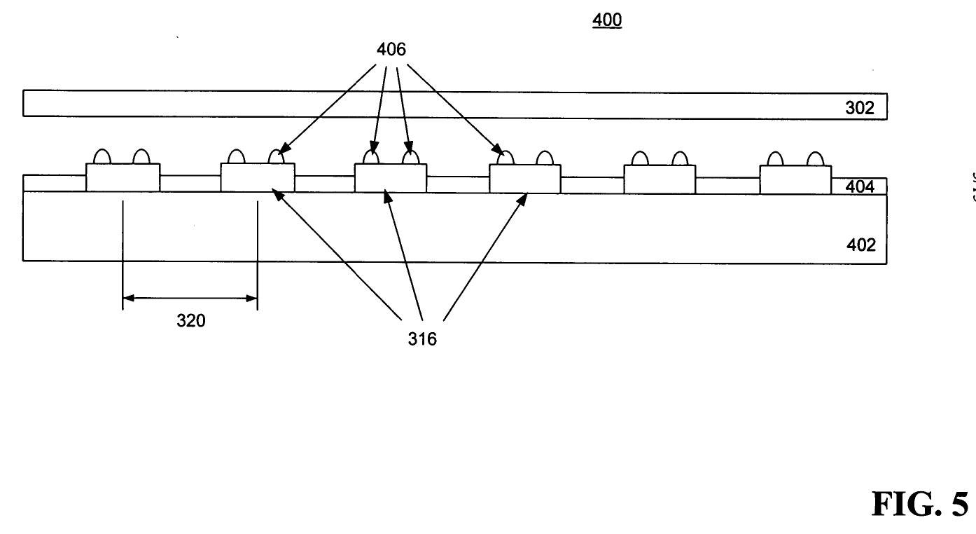

As illustrated in the figures, a freezing (FIG. 4) and peeling (FIG. 5) process may be used to fix the pitch of the dies as well as effect the removal of the stretchable substrate 302. Specifically, in this approach, as denoted by blocks 204a, 208 of FIG. 2, in order to fix the orthogonal pitches 318, 320 of the dies and to enable the relatively “clean” removal of an adhesive tape such as the substrate 302 from the dies of the array of dies 316, the substrate 302, with the array of dies thereon, is placed against a plate 402 (with the dies sandwiched in between), and a solidifiable substance 404, such as de-ionized, distilled water is introduced in the interstitial spaces 320 between the dies 316 of the array. The solidifiable substance 404 can also be the carrier that is cut into strips during the linear aggregation step, as explained below. Preferably, the height of solidifiable substance 404 is lower than the total thickness of the dies so that a portion of the die is exposed out of the layer of solidifiable substance 404. The temperature of the solidifiable substance 404 is then lowered to be below its freezing point such that it is changed in state to form a solid block, and such that it holds the array of dies 316 at the desired pitches 318 and 320. Then, in step 208, the substrate 302 is peeled away from the array of dies 316 to expose a plurality of contacts 406, with the array of dies 316 still being held by the solidified substance 404, as shown in FIG. 5.

As those of skill in the art will appreciate, the present invention provides for the separation of dies from adhesive tape with minimal damage during the adhesive tape removal and separation process, and also enables the dies 316 of to be freed of the adhesive tape relatively cleanly. In addition, the position and pattern of orientation of the devices, as disposed on the original tape or another tape if the array has been stretched or transferred multiple times, is preserved. Further, the removal of the substrate from the array of the dies 316 and their re-positioning within the array is effected with no damage to the dies themselves.

4.2 Laminate a UV-detackable tape.

Referring again to FIG. 2, and specifically to step 204b, another approach second approach for removing the substrate 302 and preparing the array of dies 316 for linear aggregation is to coat or laminate the wafer. In one embodiment, this involves the use of a thick substrate polyethyleneterephthalate(PET or other similar material) on which the plurality of dies need to be transferred before the linear aggregation of the chips is performed.

In one embodiment, UV-curable materials may be doped with different chemical additives to form free-standing chip sheets, which may be optically transparent or high opacity white. The chemical formulations are chosen so that, preferably, after the UV curable materials are solidified under UV irradiation: (a) the adhesive tapes can be easily peeled off from UV solidified chip sheets; (b) the chip surfaces are exposed on at least one side of the free-standing chip sheets; and (c) the chips or dies embedded in the chip sheets can be easily peeled off or transferred from the chip sheets onto other substrates, such as another adhesive sheet, with a 100% chip transfer.

In one embodiment, the UV curing process is optimized so that the free-standing chip sheets can be formed under the UV light with suitable curing time and uniform sheet thickness. Further, the formed chip sheets preferably has enough stiffness and elasticity to act as a resilient chip carrier, and also be easily cut into a specified shape, such as the desired chip bar. The heat stability of the UV cured chip sheets should also be designed to go through the NIR chip bonding process, as described below.

The peeling and transfer of the substrate 302 may be performed with the dies coated with UV- or heat-detackable adhesives. The chips can be totally transferred from one adhesive surface to another due to the different adhesions of the adhesives under different conditions. In one embodiment, heat-detackable pressure sensitive adhesives (PSAs) are applied for the process of peeling and transfer of the dies. For example, heat-detackable PSAs that exhibit an enhanced peeling force at room temperature and detackable behavior at temperature of 50-65 C. may be used. Preferrably, the PSA formulation should result in a heat detackable PSA having a peeling force that matches the chip transfer force at room temperature. In another embodiment, UV-detackable adhesives may be used. One exemplary UV-detackable adhesive that may be used is the 203DF adhesive as available from Avery Dennison Corporation. One exemplary heat-detackable adhesive is the 992-120 3-series of adhesives, also available from Avery Dennison Corporation.

In other embodiments, instead of using a UV-curable material a disk composed of thin glass, sodium chloride (NaCl) crystal or other material may be used. An UV-detackable adhesive or a water soluble adhesive is used to attach this disk on the non-active side of the expanded wafer.

4.3 Linear Aggregation

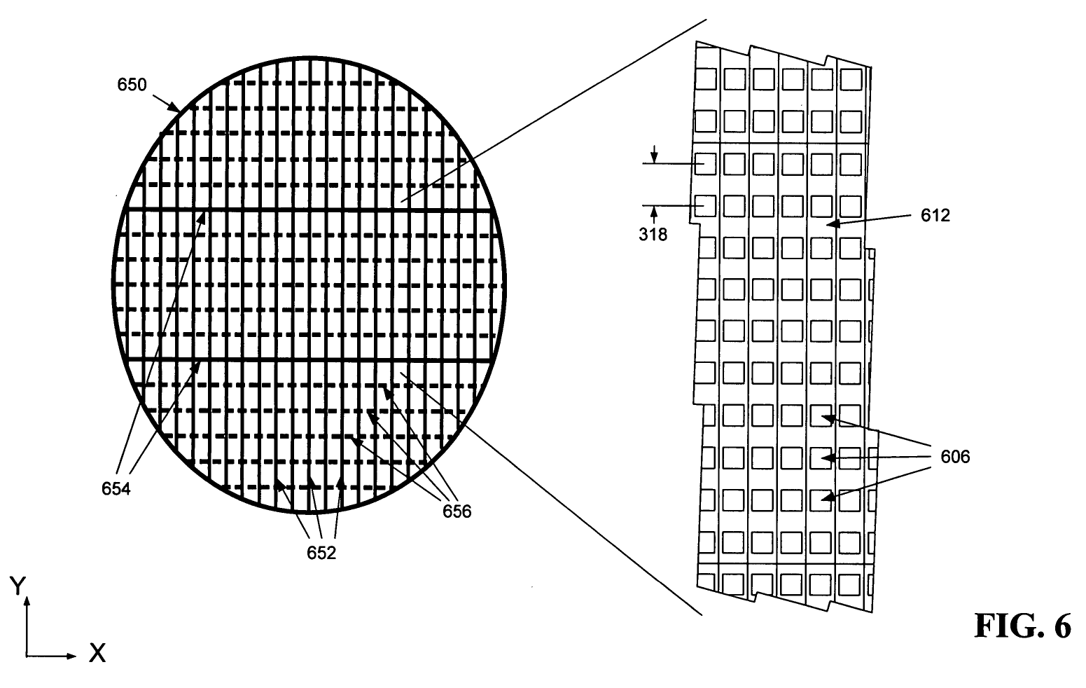

After the substrate 202 has been removed and the rigid body has been formed using ice, cured UV material, or other material discussed above, the dies will undergo the linear aggregation process 108. As illustrated by FIG. 6, in one embodiment, the linear aggregation process 108 includes cutting a rigid body 650 according to all Y direction streets 652 and periodically according to X directions 654 to singulate linear aggregations of dies 606. Each linear aggregation of dies 606 is carried on a linear die carrier 612. In one embodiment, as shown in the figure, each linear die carrier 612 includes 10 dies. It should be noted that the number of dies per linear die carrier may be variable and, correspondingly, a higher number of dies per linear die carrier would

5 Placement of Strips on Straps

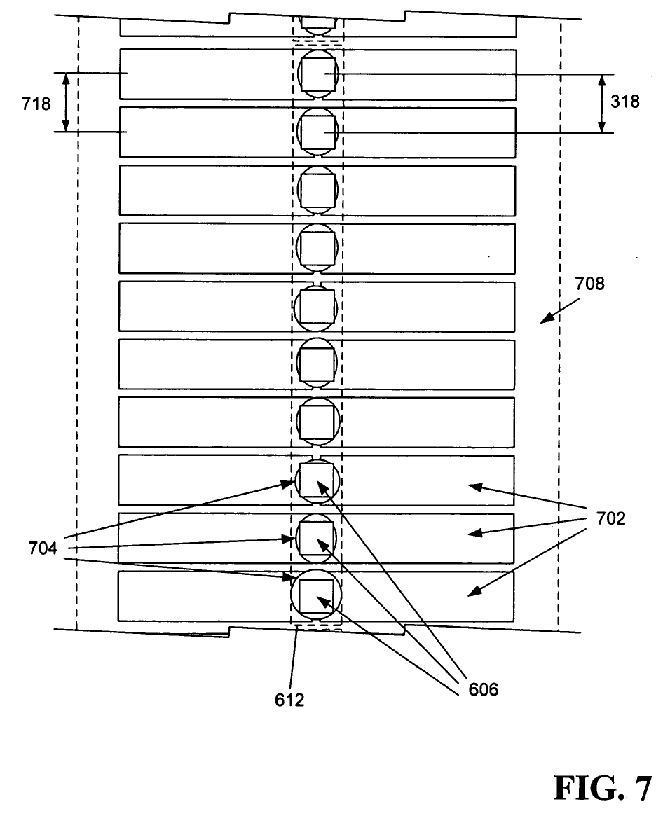

Continuing with step 110a of FIG. 2 and referring to FIG. 7 as an illustration of an exemplary process for attaching the linear aggregation of dies 606 from the array of dies 316 to a plurality of straps 702 mounted on a strap support substrate, or web 708, by overlaying the dies on the straps 702 in a direct contact approach. In one embodiment, a modified die attach machine is used to pickup the linear aggregations of dies and place them at predefined positions on web 708 containing the straps 702. As discussed herein, the dies may be presented active side facing up or down according to the contact method (direct or indirect). In this case, where the dies are placed with active side down (i.e., where the contact pads of the dies are facing down), each die in the linear aggregation of dies 606 are attached to a respective pair of straps with an adhesive 704.

In one preferred embodiment of the present invention, adhesive 704 is an anisotropic conductive adhesive (Z-axis conductive adhesive). As shown in the top portion of FIG. 7, the web 708 is illustrated with a dotted outline to represent that it is only a portion of a support structure that may contain more straps that are not shown. In one preferred embodiment of the present invention, the size of the orthogonal pitch 318 between the dies in the linear aggregation of dies 606 are matched to a respective corresponding orthogonal pitch 718 of the plurality of straps 702 in such a way that the contacts of the dies will be positioned for contact with a respective contact location on the plurality of dies. Thus, also referring back to FIG. 6, previously the substrate 202 on which the array of dies 316 was displaced was stretched such that uniform spaces 656 are created in the X direction of the wafer such that the final pitch 318 between the dies matches the pitch 718 of the straps 702, or, if it is impractical to stretch the substrate to reach a pitch that is equal to the pitch 702 of the straps, then using additional stretching operations to reach the needed pitch. In FIG. 7, it is assumed that the pitch 318 between the dies has been made equal to the spacing of the pitch 718 between the straps.

In the approaches discussed herein, the linear die carriers can be picked by special vacuum head directly from the wafer or they may be presented by vibratory feeders to the vacuum head of a pick and place (die attach) machine.

6 Strap Attachment/Bonding

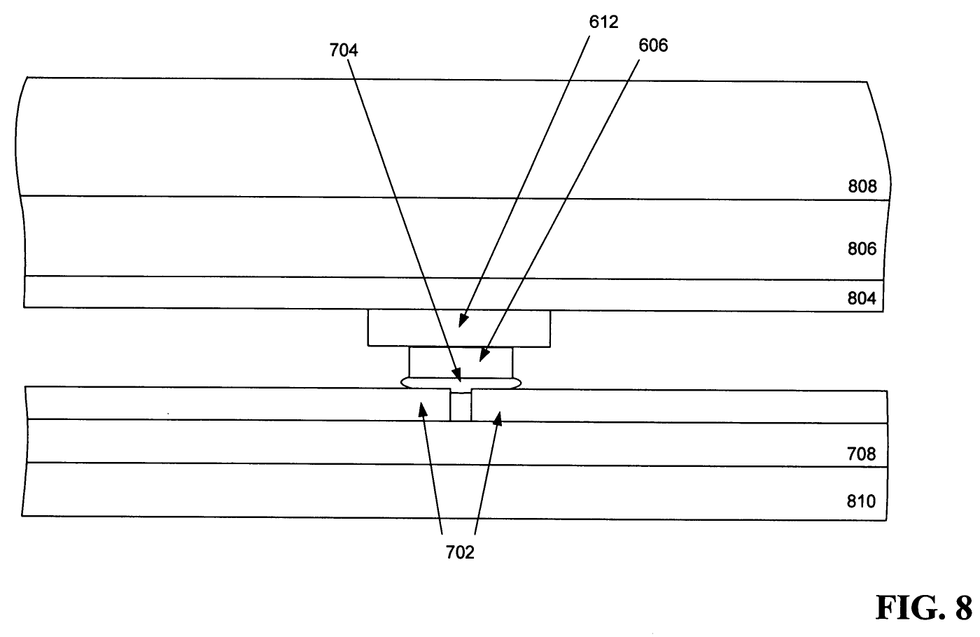

Those of skill in the art will appreciate that, although each die is “tacked”, or attached to a respective pair of straps by the adhesive 704, as described above, the adhesive is not cured and no electrical coupling is necessarily formed between the contact pads on the dies and the straps until a curing process is performed. In step 112a of FIG. 2, a NIR bonding process is performed to cure the adhesive 704. FIG. 8 illustrates such a curing of the bond of the subset of dies 606 that were attached to the plurality of straps 702 with adhesives 704, as previously illustrated in FIG. 7, to form a strap assembly in accordance with one preferred embodiment of the present invention. Specifically, a pair of platens 810 and 806 forces together the linear die carrier 612 with the linear aggregation of dies 606, the adhesives 704, and the pair of straps 702. The provision of near infrared (NIR) energy from a NIR emitter chamber 808 and a small amount of pressure by the platens cause the adhesives 704 to set and an electrical connection to be made between the contacts on each of the dies to a respective contact on each of the straps. A resilient layer 804 enables the pressure to be applied to the strap assembly uniformly. In one preferred embodiment of the present invention, the platen 806 and resilient layer 804 are made of quartz and silicon, respectively, as quartz and silicon are nearly transparent to NIR. The chip bonding to 708 web by NIR process may be performed with or without pressure.

7 Connector Printing/Wirebonding

In the approach described for steps 108a, 110a and 112a, the linear aggregation of dies are placed active side down on the printed or etched connectors of strap wings. In another embodiment, as described herein, a linear aggregation of dies 906 is placed active side up, where the contacts 904 of each die are facing upwards, on a non-conductive web 908 between a plurality of strap electrodes 902. As seen in the figure, the placement is between each of the pair of wings of each strap.

In one embodiment, the linear aggregation of dies 706 can be presented to the picking head and placed on web 908, with epoxy dispensed at selected locations. Specifically, in one embodiment, adhesive is dispensed at the locations where the linear carriers of dies are to be seated, or, in another embodiment, an epoxy film is laminated at those locations.

Further, in one embodiment, the dispensed epoxy are pre-cured to keep the linear aggregation of dies in place. Radiating the bars of dies with UV and remove the rigid supporting substrate (tape plus coating). The dies are now presented active sides up and attached to the strap web at constant distances.

Other than the use of known wire bonding processes to electrically connect the dies to the straps, another process that may be used for connecting the die input/outputs to the strap electrodes is an inkjet copper printing process as described by The Technology Partnership plc (TTP) in Melbourn Science Park, Melbourn, Royston Herts. SG8 6EE, UK. In one embodiment, the strap web is already presented with printed (or stamped) straps. In another embodiment, the strap web can be presented without any straps, in which case the whole strap may be printed, starting from the chip input/output. Specifically, the chip connectors may be extended by thicker Cu aisles so it can be later connected to the antenna electrodes by a plurality of printed connector strips 950.

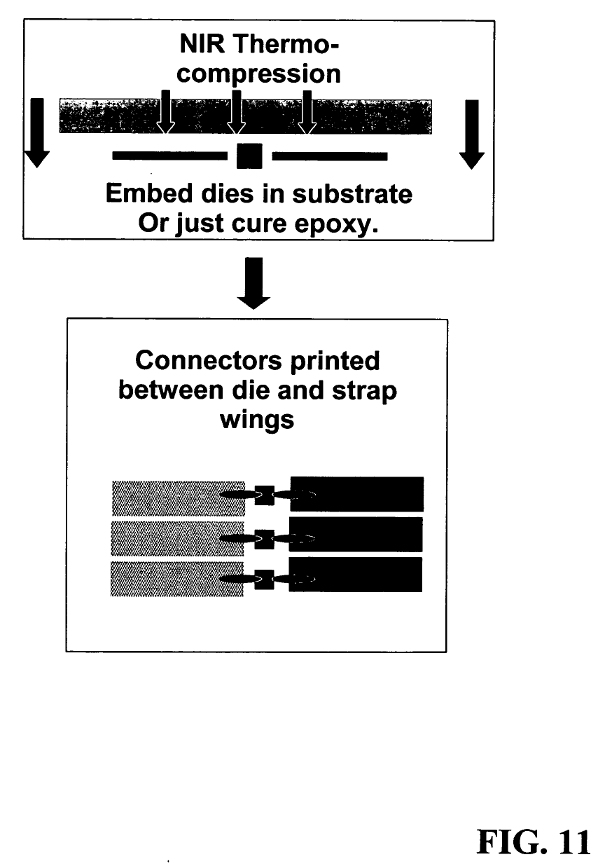

In this embodiment, as illustrated in FIG. 11, NIR thermocompression may be used to sink the dies into the strap carrier substrate, with the contacts of the dies above the substrate, so that the contacts on the dies will be at the same height as the straps for printing. Preferably, the thickness of the strap carrier substrate is lower than that of the height of the dies.

In another embodiment for higher speed inkjet printing, the active side of the chips (except on the inputs/outs) may be coated with a copper (Cu) repellant coating prior to dicing or expansion. The copper printing will be rejected from all surfaces coated by the copper except the connectors. This process requires lower precision printing. Specifically, this step permits the printer to print copper on the connectors of the chips without requiring a vision systems to achieve the desired printing accuracy.

8 Examplary Process

As described herein, the die detachment and separation process of the present invention provides manufacturers the ability to perform batch processing of a multiple number of dies simultaneously, providing volumes that surpasses those achievable by such inherently slower approaches as the one-by-one pick-and-place process. The present invention provides these benefits through an approach referred to as linear aggregation, a process where a linear grouping of chips are removed from a wafer, each of which is separated, or spaced apart, at a distance where a multiple thereof will match the distance in pitch of the straps. Then, after the application of a coating to the back of the diced expanded wafer to form a material that is preferably hard enough to keep the dies together after the backing tape has been removed.

In one embodiment, the coating/curing steps are performed as follows:

1. Coat a new tape with the material in liquid form that is laminated onto the wafer (which is on regular UV backing tape).

2. Cure the material and remove the corresponding tape from the wafer. The wafer is now only on the UV backing tape, the chips are held to each other by the cured material.

3. May dispose (e.g., flip) the dies active side up or down according to the next step.

4. Cut the hardened streets of the wafer along the X direction in order to singulate the column of dies with uniform pitch between them. Cut also in Y direction in order to get aggregations of, in one embodiment, 10 to 20 dies (rigid rods/columns of 10-20 dies each).

5. Use a simple pick and place machine with vision system to pick the linear aggregation of dies and place them on the strip of straps active side down with an adhesive such as epoxy already dispensed on the connectors. This web is presented by precise indexing. The picking head may be a vacuum head in rectangular shape with a sharp side where vacuum picks the dies. The indexer will move the strap web until there it find free strap connectors and places the next linear aggregation of die onto the web starting from this position.

6. Use heat by Infrared (IR) or Near IR (NIR), UV-exposure, or other methods to remove the rigid body. The coated material must be very thin because it has to either vaporize under NIR (or IR) or melted to cover areas of the strap outside of the conductive areas (where the linear aggregation of dies are placed perpendicular to the strap aisles).

As discussed in step 5, the dies are placed on predefined positions dispensed with epoxy before the bar of dies is placed on the web of straps. This pre-cure step is used to fix the dies in position, and loosen the tack between the dies and the rigid body. So the rigid body may be removed.

7. Use NIR thermocompression to bond-cure the dies on strips.

The processes described herein could permit high speed die attachment to straps by placing, bonding, and then curing multiple dies simultaneously on strap web. It is estimated that, in one embodiment, a die attach machine will be able to place up to 8000 bars of 20 mm lengths per hour, and, assuming that each die is 1 mm in size as measured along the length of the bar, and the pitch between dies is 2.5 mm, then the process may be able to reach 64,000 dies, or units, per hour (20 mm [length of bar]/2.5 mm [length of die and pitch]=8 dies/bar×8000 bar/hr=64,000 dies/hr).

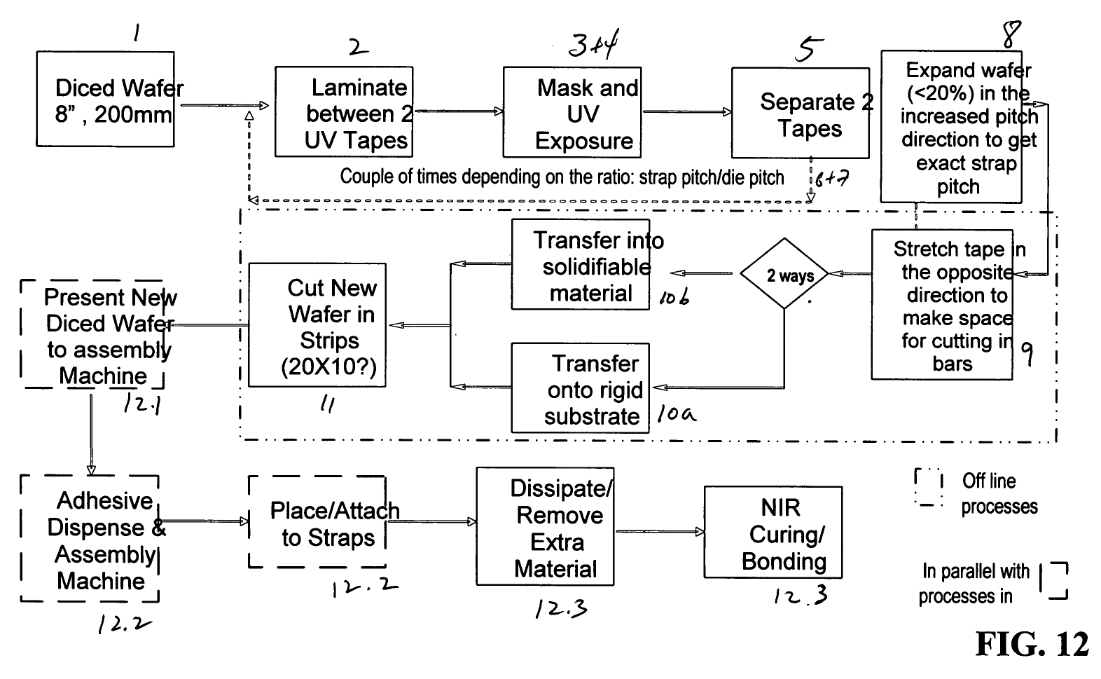

FIG. 12 illustrates an process for creating an RFID strap assembly, comprising the steps of:

1. Receive diced wafer on UV tape from vendor.

2. Laminate another UV tape on top of the wafer and place mask on both sides of the wafer.

3. The mask features open lines of the same thickness as the dies. The open lines are made at intervals corresponding to an entire pitch of the dies that almost equals the smaller pitch of the straps on the web of straps.

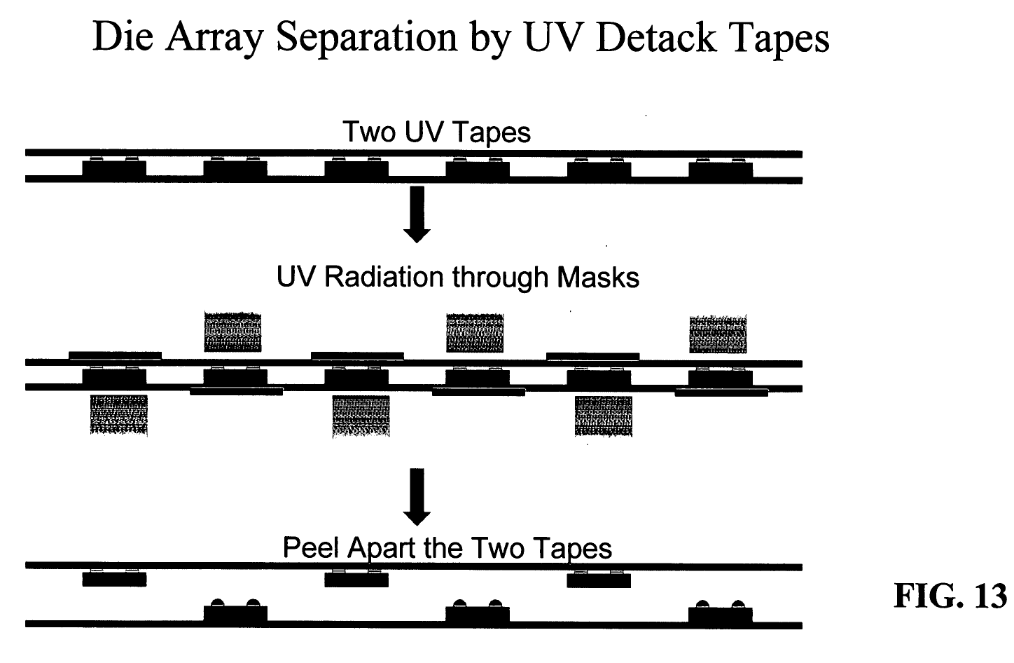

4. The wafer with masks is radiated in a double side UV chamber (see FIG. 13).

5. The tapes are then separated (see FIG. 13). We obtain one tape with die pitches in one direction very close to the strap pitches (call it T1) and one tape for the rest of the dies staying on the original tape.

6. The points 2 to 4 are repeated with the same mask to get other tapes of the same pitches as the tape T1. If the pitches of straps is 4 mm and the pitches of dies is 1 mm we obtain 4 tapes of the type T1 from the original wafer backing tape (see FIG. 13).

7. The tapes may need additional transfers to new tape to get the right face of the chips up or down according to other embodiments of the inventions.

8. If the ratio of the pitches is not an entire number, the new tapes are stretched to get to the lower strap pitches in the direction that is already separated.

9. The tapes are also stretched in the opposite vertical direction to give space for making bars (cutting, etc.)

10. The “n” new tapes with their dies separated in one direction to the pitches of the straps are then:

a. either transferred onto a rigid substrate already coated with a heat detackifible adhesive, or,

b. transferred into solidifible materials to keep the dies pitches unchanged.

11. The new “wafers” have backing tapes on either the rigid surface or the solidified material. The wafers are then cut into bars of a predetermined length (e.g., 20 mm long) in the direction of the higher pitch. For example, for a strap pitch of 2.5 mm, a 20 mm bar would contain 8 chips.

12. These wafer are presented to the assembly machine which sees them as wafers cut into large rectangular dies.

The following is an explanation of the online process of the flow chart of FIG. 12, as continued from above.

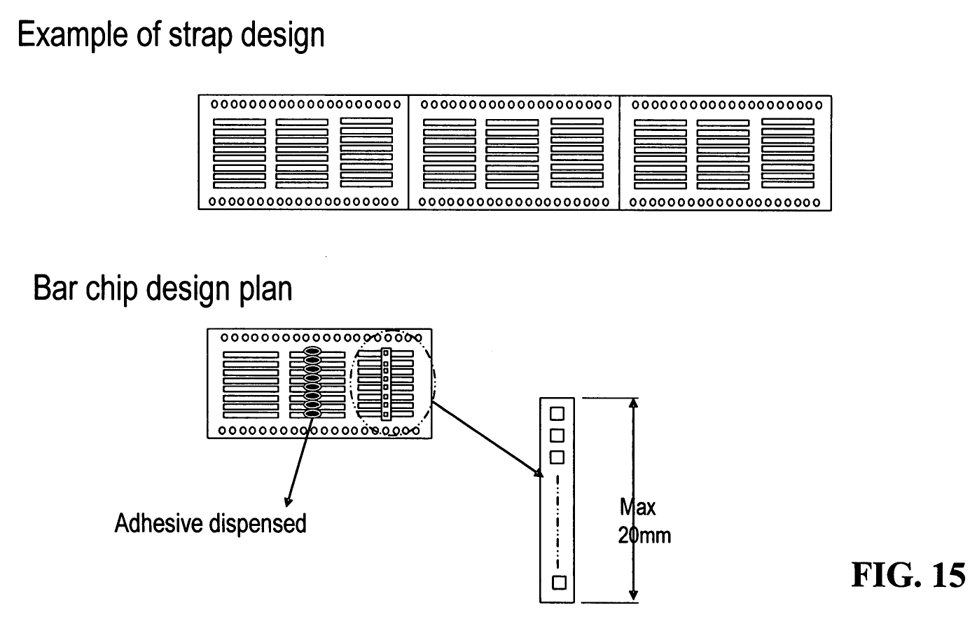

12.1. The assembly machine gets the new wafers with large dies as input, with special bond heads of the same size as the bars, picks the bars and places them on the web of straps looking for the first and the last dies on the bar to precisely placed on the already tacky positions on the straps (see FIG. 15).

12.2. The tackiness of the die positions comes from adhesive dispensed by the assembly machine or in a preferred embodiment from a narrow epoxy film (ACF, etc.) laminated on the same positions by the same machine.

12.3. The dissipation or removal step depends on the approach for making bars:

a. If the dies are located on a heat detack adhesive coated rigid body (i.e., thick PET), in one preferred embodiment the body is first radiated for a short time (1 min.) by NIR to precure the epoxy, then a Teflon coated quartz is placed on it and radiated with NIR during around 3 min to cure the epoxy. The heat detack coating on the PET will become loose after the radiation, and a vacuum system removes it from the top of the construction.

b. In cases where a solidifiable material is used, the solidifiable material can be melted, dissipated or evaporated, depending on the type of solidifiable material used, before NIR curing of the epoxy.

12.4. Thus, multiple of chips are consequently placed and bonded onto multiple of straps, instead of single dies being picked and placed.

The embodiments described above are exemplary embodiments of the present invention. Those skilled in the art may now make numerous uses of, and departures from, the above-described embodiments without departing from the inventive concepts disclosed herein. Accordingly, the present invention is to be defined solely by the scope of the following claims.

1. A method for creating semiconductor devices comprising:
providing an array of semiconductor dies mounted to a substrate and spaced apart at a first pitch;
stretching the substrate to match the first pitch to a second pitch between a pair of straps in a plurality of straps;
fixing the array of semiconductor dies in a solidifiable material; and,
cutting the solidified material into strips.

2. The method of claim 1, further comprising placing each strip using an assembly machine onto a corresponding plurality of straps disposed on a strap web.

3. The method of claim 2, further comprising electrically coupling each semiconductor die on each strip to a respective strap in the corresponding plurality of straps.

4. The method of claim 1, wherein the step of cutting the solidified material into strips comprises cutting the solidified material along a direction parallel to the direction along which the substrate is stretched.

5. The method of claim 1, wherein stretching the substrate to match the first pitch to the second pitch comprises stretching the substrate in two dimensions.

6. The method of claim 1, wherein fixing the array of semiconductor dies in a solidifiable material comprises coating the diced expanded wafer with a solidifiable material.

7. The method of claim 1, wherein cutting the solidified material into strips comprises cutting the strips in a direction perpendicular to a long direction of the strips.

8. The method of claim 7, wherein transferring the array of semiconductor dies to a rigid substrate comprises affixing the array of semiconductor dies to the rigid substrate with a UV-sensitive adhesive.

9. The method of claim 1, wherein the substrate is a wafer sawing tape.

10. The method of claim 1, wherein the substrate is a tape coated with an ultraviolet sensitive adhesive.
